(19) United States
(12) Patent Application Publication
(10) Pub. No.: US 2026/0275530 A1
(43) Pub. Date: Sep. 17, 2026

(54) EYEWEAR WITH ANTIBACTERIAL COATING

(71) Applicant: Zenni Optical, Inc., Novato, CA (US)

(72) Inventors: Steven LEE, Barrington, IL (US); Julia ZHEN, Novato, CA (US); Feng LIU, Zhenjiang (CN); Xule CHEN, Zhenjiang (CN); Liangliang Mao, Zhenjiang (CN)

(21) Appl. No.: 19/564,026

(22) Filed: Mar. 11, 2026

Related U.S. Application Data
(60) Provisional application No. 63/770,319, filed on Mar. 11, 2025.

(51) Int. Cl. C23C 28/00; B29D 11/00; C23C 2/02; C23C 2/04; C23C 2/28; C23C 14/28; G02B 1/116; G02B 1/14; G02B 1/18

(52) U.S. Cl. CPC C23C 28/325; B29D 11/00865; C23C 2/024; C23C 2/04; C23C 2/28; C23C 14/28; C23C 28/3455; G02B 1/116; G02B 1/14; G02B 1/18

(57) ABSTRACT

Eyewear can include lenses that have a coating that reduces or mitigates the presence of microorganisms on the eyewear. For example, the lenses can include one or more coatings. Optionally, the coatings can include one or more of a hard coating, an antibacterial anti-reflection coating, and an antibacterial hydrophobic coating. The hard coating can be dip-coated onto the lenses, and the antibacterial anti-reflection coating can be vacuum coated onto the hard coatings. The antibacterial anti-reflection coating can be a layered structure including one or more of SiO₂, ZrO₂, ITO, ZnO, and Al₂O₃. Different coatings can be applied in various combinations and thicknesses to create lenses with different effects. Optionally, the coatings on the lenses can be configured to target one or both of Escherichia coli ATCC 8739 and Staphylococcus aureus ATCC 6538P.

### CROSS-REFERENCE TO RELATED APPLICATIONS

This application claims priority under 35 U.S.C. 119(e) to, and the benefit of, U.S. Provisional Application No. 63/770,319, filed Mar. 11, 2025, the entirety of which is incorporated herein by reference.

### BACKGROUND

### Field of the Inventions

The present disclosure relates to eyewear, and more specifically, to improved lens technology that can reduce or eliminate bacteria on eyewear lenses.

### Description of the Related Art

The use of eyewear that adapts to different environmental and lighting conditions has become increasingly common, providing enhanced comfort and utility for users in their daily lives. Advances in lens technologies, such as photochromic and polarized lenses, have made it possible for eyewear to offer improved performance by adjusting to varying light levels or reducing glare. These features have expanded the applications of eyewear beyond basic vision correction, making them integral tools for a wide range of activities and environments.

Despite these advancements, developing eyewear that effectively meets the demands of everyday life presents significant challenges. Factors such as temperature fluctuations, which can affect lens clarity and material performance, and specific scenarios like driving, where rapid light adjustments are critical, add complexity to the design process. Ensuring that eyewear remains comfortable, durable, and reliable across diverse conditions requires a careful balance of innovation, material science, and user-centered design.

### SUMMARY

In accordance with at least some embodiments disclosed herein is the realization that eyewear lenses become contaminated with microorganisms. Accordingly, eyewear can become contaminated with microorganisms and such as bacteria and fungi. To make matters worse, microorganisms may spread along the surface of eyewear and lenses because these materials often have nonporous surfaces, which are designed to prevent the formation of fog and repel dirt and oil but may be suitable for microorganism reproduction. As a result, bacteria and fungi can form colonies on eyewear lenses that survive for extended periods of time. Further, if a person touches her glasses and then touches her eyes (e.g., when she takes off her glasses to rub her eyes), she can easily transfer bacteria and fungi to her eyes. This can result in irritation and infection.

One conventional approach to eliminating microorganisms on eyewear is wiping the eyewear with rubbing alcohol or sterilizing wipes. However, rubbing harsh chemicals into eyewear can damage lens coatings on the eyewear (e.g., coatings designed to reduce glare, prevent fog, and reflect light such as harmful blue light and near infrared light).

Another conventional approach to eliminating microorganisms on eyewear is washing the eyewear with soap and water. However, this requires a lot of effort, care, and time to avoid damaging the lenses. For example, soap should be used sparingly so as to not damage the lens coatings. Additionally, only soft cloths, such as microfiber cloths, should be used to dry the eyewear to avoid scratching. In the modern age, people live fast-paced lives and are, unfortunately, unlikely to take the time required to properly clean their eyewear by hand.

In accordance with at least some embodiments disclosed herein is the realization that eyewear (such as glasses, goggles, or other eyewear) can have lenses with antibacterial properties. Specifically, the antibacterial lens can comprise a resin lens with a hard coating, an antibacterial anti-reflection coating, and an antibacterial hydrophobic coating.

The present disclosure addresses these and other challenges by providing innovative systems, methods, and devices that each have several innovative and beneficial aspects, no single one of which is solely responsible for the desirable attributes disclosed herein.

The systems, methods, and devices of this disclosure each have several innovative aspects, no single one of which is solely responsible for the desirable attributes disclosed herein.

Additional features and advantages of the subject technology will be set forth in the description below, and in part will be apparent from the description, or may be learned by practice of the subject technology. The advantages of the subject technology will be realized and attained by the structure particularly pointed out in the written description and embodiments hereof as well as the appended drawings.

It is to be understood that both the foregoing general description and the following detailed description are exemplary and explanatory and are intended to provide further explanation of the subject technology.

### BRIEF DESCRIPTION OF THE FIGURES

Various features of illustrative embodiments of the inventions are described below with reference to the drawings. The illustrated embodiments are intended to illustrate, but not to limit, the inventions. The drawings contain the following figures:

FIG. 1 illustrates an exploded view of the layers that constitute the antibacterial lens, according to some embodiments of the present disclosure.

FIG. 2 illustrates antimicrobial capabilities of the antibacterial lenses, according to some embodiments.

FIG. 3 illustrates the spectrum of radiation that is transmitted by the first example of the antibacterial lens, according to some embodiments.

FIG. 4 illustrates the spectrum of radiation that is transmitted by the third example of the antibacterial lens, according to some embodiments.

### DETAILED DESCRIPTION

It is understood that various configurations of the subject technology will become readily apparent to those skilled in the art from the disclosure, wherein various configurations of the subject technology are shown and described by way of illustration. As will be realized, the subject technology is capable of other and different configurations and its several details are capable of modification in various other respects, all without departing from the scope of the subject technology. Accordingly, the summary, drawings and detailed description are to be regarded as illustrative in nature and not as restrictive.

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be apparent to those skilled in the art that the subject technology may be practiced without these specific details. In some instances, well-known structures and components are shown in block diagram form in order to avoid obscuring the concepts of the subject technology. Like components are labeled with identical element numbers for ease of understanding.

In accordance with at least some embodiments disclosed herein is the realization that eyewear is a breeding ground for microorganisms (i.e., bacteria), which can easily irritate and infect a wearer. Conventional means of properly cleaning glasses require a degree of time and care that most people are unwilling, or even unable, to dedicate to their glasses. Consequently, people who wear glasses rarely sanitize their glasses, which means that the microorganisms spreads across the lenses. Therefore, it is desirable to have eyewear lenses that sanitize themselves.

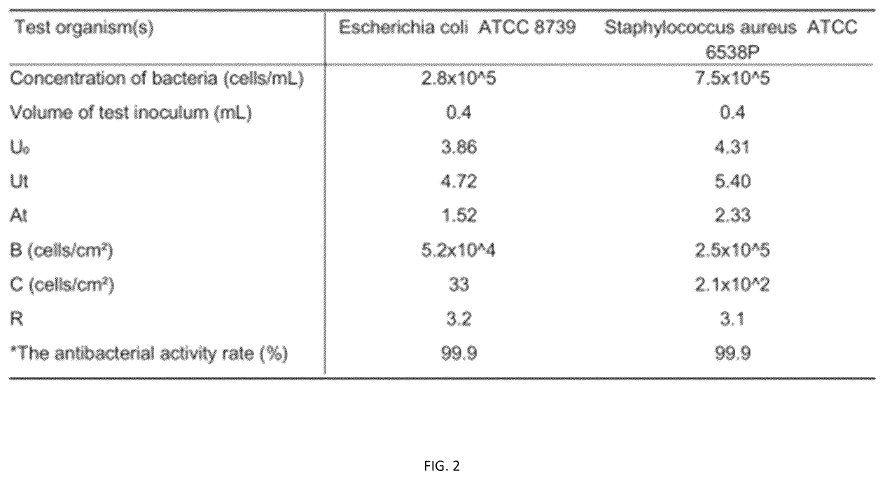

It is also valuable to have lenses that reduce the amount of glare perceived by the wearer and transmit a broad spectrum of visible light to the wearer. However, traditional lenses rely on inorganic materials to achieve these effects, and these inorganic materials cannot reduce or eliminate microorganisms. Accordingly, the present disclosure represents a significant advancement over traditional lenses because the lenses disclosed herein are produced with a coating structure that can simultaneously reduce, mitigate, or eliminate microorganisms, reduce glare, and transmit visible light. In some embodiments, lenses described herein can reduce or eliminate about 99.9% of microorganisms such as Escherichia coli ATCC 8739 and Staphylococcus aureus ATCC 6538P, while also transmitting about 97% of visible light (i.e., light with a wavelength between about 380 nm and about 780 nm). These features are described in greater detail below, with respect to Table 1 and FIGS. 2-4.

Additionally, the lenses described herein can have a surface hardness of about 6 H or greater, which can effectively limit the impact of surface scratches on the antibacterial lens. In some embodiments, the antibacterial lenses can have a surface hardness of about 7 H or greater.

Moreover, the antibacterial lens can be hydrophobic (with a water drop angle of at least 114°, compared to an ordinary water drop angle of) 110°, which can effectively reduce, mitigate, or prevent fog, oil, dirt, and fingerprints from forming on the lens and obstructing the wearer's field of vision.

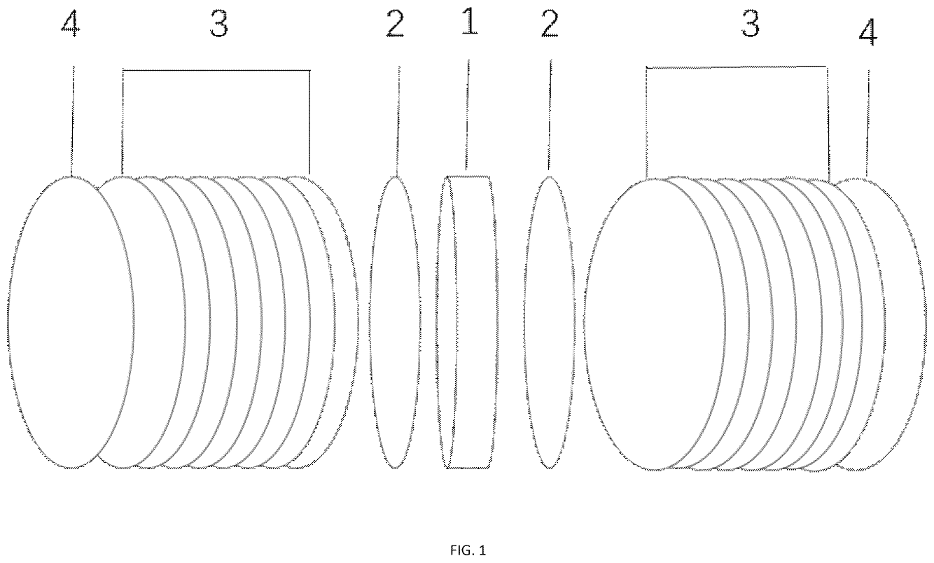

FIG. 1 illustrates an exploded view of the layers that constitute the antibacterial lens, according to some embodiments of the present disclosure. In particular, FIG. 1 shows a coating structure that is symmetrical about an optical lens 1. The symmetrical coating structure can ensure consistent optical performance of the lenses in both directions. Both sides of the lens 1 can be coated with a hard coating 2 (which can also be referred to as a hardened layer). Similarly, each hard coating 2 is coated with an antibacterial anti-reflection coating 3, which is an eight-layer structure that includes a first SiO2 layer, a first ZrO2 layer, a second SiO2 layer, a second ZrO2 layer, a first ITO layer, a first ZnO layer, a first Al2O3 layer, and a third SiO2 layer. SiO2 and ZrO2 have refractive properties that contribute to the anti-reflection function of the antibacterial anti-reflection coating 3. ZnO provides antibacterial efficacy while also enhancing the anti-reflection function. Al2O3 provides a durability that protects the other layers in the antibacterial anti-reflection coating 3. ZnO is positioned between ITO and Al2O3 to maximize the antibacterial efficacy of ZnO, optimize optical performance of the antibacterial anti-reflection coating overall, and maintain the durability of the antibacterial anti-reflection coating. The first SiO2 layer is adjacent to the hard coating 2, and the third SiO2 layer is adjacent to an antibacterial hydrophobic coating 4. Each of these coatings is described in greater detail below.

The lens 1 can comprise a flat structure with two opposite sides (i.e., a front side and a back side). The two opposite sides can be referred to as the first surface and the second surface. The lens 1 can be made with a resin material.

Optionally, the lens can have a refraction index between about 1.34 and about 1.89. Optionally, the lens can have a refraction index between about 1.49 and about 1.74. Optionally, the lens can have a refraction index of about 1.56. Optionally, the lens can have a refraction index of about 1.49.

Optionally, the hard coating can be dip-coated onto the first and second surfaces of the lens. By applying the hard coating directly to the lens, the lens becomes scratch-resistant and durable, which is essential for protecting the more sensitive antibacterial anti-reflection coating. In some embodiments, the hard coating can be an organosilicon hard coating liquid or a silicone material. In other embodiments, the hard coating can be an abrasion resistant coating or a polysiloxane-based thermal cure coating with a 1.49 refraction index (e.g., a liquid solution of MP 7110 with a mass percentage of 22%).

The hard coating can have a thickness between about 0.5 μm and about 12 μm. Optionally, the hard coating can have a thickness between about 1 μm and about 10 μm.

An antibacterial anti-reflection coating is disposed on each hard coating. The antibacterial anti-reflection coating can be vacuum coated onto the lens and the hard coating. The anti-reflection coating has a layered structure that includes a first SiO2 layer, a first ZrO2 layer, a second SiO2 layer, a second ZrO2 layer, a first ITO layer, a first ZnO layer, a first Al2O3 layer, and a third SiO2 layer. The layered structure is arranged with the first SiO2 layer being nearest the lens in the third SiO2 layer being farthest away from the lens.

The thickness of the layers in the layered structure varies throughout the structure. In some embodiments, the first SiO2 layer is between about 70 nm and about 190 nm thick. The first ZrO2 layer is between about 1 nm and about 65 nm thick. The second SiO2 layer is between about 1 nm and about 85 nm thick. The second ZrO2 layer is between about 10 nm and about 90 nm thick. The first ITO layer is between about 1 nm and about 15 nm thick. The first ZnO layer is between about 1 nm and about 15 nm thick. The first Al2O3 layer is between about 1 nm and about 20 nm thick. Finally, the third SiO2 layer is between about 50 nm and about 160 nm thick.

The thinner layers of ITO, ZnO, and Al2O3 help reduce the weight of the lens without sacrificing the benefits of these materials (e.g., antibacterial efficacy, optical transmission, enhanced durability, etc.). Moreover, SiO2 and ZrO2 are more prominent in the layered structure because they facilitate light interference. The thicknesses of these materials can be altered throughout the layered structure to create different light interference effects, depending on the precise function desired by a particular embodiment of the lenses.

In other embodiments, the first SiO2 layer is between about 80 nm and about 180 nm thick. The first ZrO2 layer is between about 5 nm and about 60 nm thick. The second SiO2 layer is between about 5 nm and about 80 nm thick. The second ZrO2 layer is between about 20 nm and about 80 nm thick. The first ITO layer is between about 5 nm and about 10 nm thick. The first ZnO layer is between about 5 nm and about 10 nm thick. The first Al2O3 layer is between about 5 nm and about 15 nm thick. Finally, the third SiO2 layer is between about 60 nm and about 150 nm thick.

Optionally, the first SiO2 layer is about 129 nm thick. The first ZrO2 layer is about 22 nm thick. The second SiO2 layer is about 25 nm thick. The second ZrO2 layer is about 40 nm thick. The first ITO layer is about 5 nm thick. The first ZnO layer is about 7 nm thick. The first Al2O3 layer is about 8 nm thick. Finally, the third SiO2 layer is about 95 nm thick.

Optionally, the first SiO2 layer is about 110 nm thick. The first ZrO2 layer is about 45 nm thick. The second SiO2 layer is about 55 nm thick. The second ZrO2 layer is about 120 nm thick. The first ITO layer is about 6 nm thick. The first ZnO layer is about 7 nm thick. The first Al2O3 layer is about 8 nm thick. Finally, the third SiO2 layer is about 90 nm thick.

Optionally, the first SiO2 layer is about 85 nm thick. The first ZrO2 layer is about 35 nm thick. The second SiO2 layer is about 60 nm thick. The second ZrO2 layer is about 100 nm thick. The first ITO layer is about 6 nm thick. The first Al2O3 layer is about 6 nm thick. Finally, the third SiO2 layer is about 85 nm thick.

An antibacterial hydrophobic coating or layer is disposed on each antibacterial anti-reflection coating. The antibacterial hydrophobic coating can have hydrophobic properties that can encourage water droplets on the lens (e.g., raindrops) to bead up and roll off the surface of the lens rather than spread out and form a thick layer of water that obscures the wearer's vision. As a result, the antibacterial hydrophobic coating can help maintain clear vision in wet conditions.

Similarly, the antibacterial hydrophobic coating can repel oil and dirt, which helps wearers keep their lenses cleaner for longer and improves visibility—in part, by optimizing the function of the layers beneath it, such as the antibacterial anti-reflection coating. Moreover, the antibacterial hydrophobic coating can comprise a silver material, which gives the coating an antibacterial quality. The antibacterial hydrophobic coating repels oil and dirt and eliminates bacteria, which means that the lenses do not require frequent cleaning. Consequently, the lenses last longer and require less maintenance than lenses without the coating structure disclosed herein.

The antibacterial hydrophobic coating also lengthens the lifespan of the lenses because, as the outermost layer, the antibacterial hydrophobic coating can protect the layers beneath it from abrasion and wear. Lenses are typically exposed to a wide range of environmental stressors, and the antibacterial hydrophobic coating can extend the life of the lenses by protecting the inner layers of the lenses against these stressors while maintaining the transparency of the lenses, as described above.

In some embodiments, the antibacterial hydrophobic coating has a thickness between about 5 nm and about 110 nm. Optionally, the antibacterial hydrophobic coating has a thickness between about 10 nm and about 100 nm. Optionally, the antibacterial hydrophobic coating has a thickness of about 35 nm, about 30 nm, or about 20 nm.

The present disclosure also includes methods for manufacturing an eyeglass lens that kills bacteria. Such a method may include providing a lens as previously described with respect to FIG. 1. The method may include surface grinding the lens to remove an outer coating. The method may further include selecting one or more appropriate correction values and processing the lens (e.g., by surface grinding or by surface processing with optical design software) to apply the appropriate correction values to the lens. In some embodiments, the lens can be a single prescription lens. In other embodiments, the lens can be a progressive prescription lens. The method may also include wiping the lens, cleaning the lens with ultrasonic waves, and drying the lens.

In some embodiments, after providing the lens, the method can include processing the lens to accommodate a single light level. In other embodiments, the lens can be processed to accommodate progressive light levels or be processed into prism lenses.

Next, a hard coating may be dip-coated or spin coated onto one or both sides of the lens. The lifting speed for applying the hard coatings can be between about 0.5 mm/s and about 5 mm/s. Optionally, the lifting speed is between about 1 mm/s and about 3 mm/s. In some embodiments, the lifting speed is about 2.5 mm/s or about 1.5 mm/s. In some embodiments, the hard coating is dip-coated or spin coated at an immersion temperature between about 10° C. and 20° C. (e.g., about 16° C.).

After the hard coating is applied to the lens, the lens and the hard coating are left to dry. The lens is dried at a temperature between about 60° C. and 70° C. for a time between about 5 minutes and 15 minutes. Optionally, the lens is dried at a temperature of about 65° C. for about 10 minutes. Next, the lens is placed in a curing oven so that the hard coating can solidify. The curing oven has a temperature between about 110° C. and about 120° C., and the lens is cured for about 170 minutes to about 190 minutes. Optionally, the lens is cured at about 115° C. for about 180 minutes.

The method may further include placing the lens (and the hard coating) in a vacuum chamber and vacuum coating antibacterial anti-reflection coatings onto each hard coating. This can include bombarding each of the hardened layers with Ar to activate the hard coatings and depositing on each of the hardened layers a layered structure that includes SiO2, ZrO2, ITO, ZnO, and Al2O3, as described above with reference to FIG. 1. The layered structure may be deposited onto the hardened layers with an electron gun, which facilitates precise and uniform application of each layer.

Vacuum coating the antibacterial anti-reflection coatings on the hard coatings can require an electron gun power between about 5% and about 55%, an anode voltage of about 80 Volts (V) to about 130 V, an anode current of about 0.5 Amperes (A) to 3.5 A, an O2 flow rate between about 0 standard cubic centimeters per minute (sccm) and about 40 sccm, and an Ar flow rate of between about 0 sccm and about 55 sccm. Additionally, the vacuum coating chamber has a temperature between about 30° C. and about 60° C. and a pressure between about 3.0×10-2 Pascals (Pa) and about 3.0×10-6 Pa. Moreover, the evaporation rates for vacuum coating the anti-reflection layer are between about 0.1 nm/s and about 3.5 nm/s for SiO2, about 0.05 nm/s and about 2.5 nm/s for ZrO2, about 0.05 nm/s and about 0.25 nm/s for ITO, about 0.005 nm/s and about 0.25 nm/s for ZnO, and about 0.05 nm/s and about 0.35 nm/s for Al2O3. Different embodiments of the antibacterial lenses are manufactured using different vacuum chamber conditions. Adjusting these conditions allows fine control over film deposition rates and material density, which enhances the layer performance for different optical properties.

After the antibacterial anti-reflection coating is applied, the antibacterial anti-reflection coating can be thermally evaporated to form an antibacterial hydrophobic coating on top of the antibacterial anti-reflection coating. While thermal evaporation is less precise than electron gun deposition, thermal evaporation can be sufficient for singular layers such as the hydrophobic coating and can help reduce the cost of manufacturing the lens. This can require a thermal evaporation power between about 5% and about 20%. Optionally, the antibacterial hydrophobic coating can be evaporated onto the lens at an evaporation rate between about 0.05 nm/s and about 0.3 nm/s.

The methods disclosed herein can be used to produce multiple embodiments of the antibacterial lens. In a first example, a lens with a 1.56 refractive index is selected and processed (e.g., by surface grinding) to have a correction value (i.e., the wearer's prescribed correction value). Pursuant to the method disclosed above, the lens is processed, wiped, ultrasonically cleaned, and dried. Next, a hard coating is applied to both sides of the lens via dip coating. Specifically, the lens is immersed in a liquid solution of MP 7110 with a mass percentage of 22% at a temperature of 16° C. with a lifting speed of 1.5 mm/s. Once the hard coating is applied to the lens, the hard coating is dried by placing the lens in an approximately 65° C. environment for about 10 minutes. Subsequently, the lens is placed in a curing oven at about 115° C. for about 180 minutes so that the hard coating can solidify.

When the hard coating is solidified, the lens (with the hard coating) is placed into a vacuum coating chamber with a temperature of 40° C. and a pressure of 3.0×10-3 Pa. As described above, Ar is used to bombard the hard coating with ion beams to activate the hard coating. Next, an electron gun is used to evaporate and deposit SiO2, ZrO2, SiO2, ZrO2, ITO, ZnO, Al2O3, and SiO2 in sequence to form the antibacterial anti-reflection coating.

The first layer of SiO2 has a thickness of about 129 nm, the first layer of ZrO2 has a thickness of about 22 nm, the second layer of SiO2 has a thickness of about 25 nm, the second layer of ZrO2 has a thickness of about 40 nm, the first layer of ITO has a thickness of about 5 nm, the first ZnO layer has a thickness of about 7 nm, the first layer of Al2O3 has a thickness of about 8 nm, and the fourth layer of SiO2 has a thickness of about 95 nm. The electron gun has a power of 35%, the anode voltage is 100 V, the anode current is 3 A, the O2 flow rate is 28 sccm, and the Ar flow rate is 40 sccm. The evaporation rate of the anti-reflection coating is about 1.3 nm/s for SiO2, about 0.6 nm/s for ZrO2, about 0.1 nm/s for ITO, about 0.1 nm/s for ZnO, and about 0.2 nm/s for Al2O3.

Finally, resistance thermal radiation is used to heat the antibacterial anti-reflection coating and evaporate the antibacterial hydrophobic coating onto the lens. The antibacterial hydrophobic coating has a thickness of about 35 nm and is applied at an evaporation rate of about 0.2 nm/s with a thermal evaporation power of about 15%.

In a second example, an uncoated lens is wiped, ultrasonically cleaned, and dried. Next, a hard coating is applied to both sides of the lens via dip coating. Specifically, the lens is immersed in a liquid solution of MP 7110 with a mass percentage of 22% at a temperature of 16° C. with a lifting speed of 2.5 mm/s. Once the hard coating is applied to the lens, the hard coating is dried by placing the lens in an approximately 65° C. environment for about 10 minutes. Subsequently, the lens is placed in a curing oven at about 115° C. for about 180 minutes so that the hard coating can solidify.

When the hard coating is solidified, the lens (with the hard coating) is placed into a vacuum coating chamber with a temperature of 40° C. and a pressure of 3.0×10-3 Pa. As described above, Ar is used to bombard the hard coating with ion beams to activate the hard coating. Next, an electron gun is used to evaporate and deposit SiO2, ZrO2, SiO2, ZrO2, ITO, ZnO, Al2O3, and SiO2 in sequence to form the antibacterial anti-reflection coating.

The first layer of SiO2 has a thickness of about 110 nm, the first layer of ZrO2 has a thickness of about 45 nm, the second layer of SiO2 has a thickness of about 55 nm, the second layer of ZrO2 has a thickness of about 120 nm, the first layer of ITO has a thickness of about 6 nm, the first ZnO layer has a thickness of about 7 nm, the first layer of Al2O3 has a thickness of about 8 nm, and the fourth layer of SiO2 has a thickness of about 90 nm. The electron gun has a power of 20%, the anode voltage is 110 V, the anode current is 1.5 A, the O2 flow rate is 30 sccm, and the Ar flow rate is 36 sccm. The evaporation rate of the anti-reflection coating is about 1.3 nm/s for SiO2, about 0.6 nm/s for ZrO2, about 0.1 nm/s for ITO, about 0.1 nm/s for ZnO, and about 0.2 nm/s for Al2O3.

Finally, resistance thermal radiation is used to heat the antibacterial anti-reflection coating and evaporate the antibacterial hydrophobic coating onto the lens. The antibacterial hydrophobic coating has a thickness of about 30 nm and is applied at an evaporation rate of about 0.2 nm/s with a thermal evaporation power of about 10%.

In a third example, a blank lens with a 1.49 refractive index is selected and processed (e.g., by surface grinding) to have a correction value (i.e., the wearer's prescribed correction value). Pursuant to the method disclosed above, the lens is processed, wiped, ultrasonically cleaned, and dried. Next, a hard coating is applied to both sides of the lens via dip coating. Specifically, the lens is immersed in a liquid solution of MP 7110 with a mass percentage of 22% at a temperature of 16° C. with a lifting speed of 2.5 mm/s. Once the hard coating is applied to the lens, the hard coating is dried by placing the lens in an approximately 65° C. environment for about 10 minutes. Subsequently, the lens is placed in a curing oven at about 115° C. for about 180 minutes so that the hard coating can solidify.

When the hard coating is solidified, the lens (with the hard coating) is placed into a vacuum coating chamber with a temperature of 40° C. and a pressure of 1.0×10-3 Pa. As described above, Ar is used to bombard the hard coating with ion beams to activate the hard coating. Next, an electron gun is used to evaporate and deposit SiO2, ZrO2, SiO2, ZrO2, ITO, Al2O3, and SiO2 in sequence to form the antibacterial anti-reflection coating.

The first layer of SiO2 has a thickness of about 85 nm, the first layer of ZrO2 has a thickness of about 35 nm, the second layer of SiO2 has a thickness of about 60 nm, the second layer of ZrO2 has a thickness of about 100 nm, the first layer of ITO has a thickness of about 6 nm, the first layer of Al2O3 has a thickness of about 6 nm, and the third layer of SiO2 has a thickness of about 85 nm. The electron gun has a power of 35%, the anode voltage is 100 V, the anode current is 3 A, the O2 flow rate is 30 sccm, and the Ar flow rate is 40 sccm. The evaporation rate of the anti-reflection coating is about 2 nm/s for SiO2, about 0.8 nm/s for ZrO2, about 0.1 nm/s for ITO, and about 0.3 nm/s for Al2O3.

Finally, resistance thermal radiation is used to heat the antibacterial anti-reflection coating and evaporate the antibacterial hydrophobic coating onto the lens. The antibacterial hydrophobic coating has a thickness of about 20 nm and is applied at an evaporation rate of about 0.1 nm/s with a thermal evaporation power of about 12%.

In a fourth example, a blank lens with a 1.56 refractive index is selected and processed (e.g., by surface grinding) to have a correction value (i.e., the wearer's prescribed correction value). Pursuant to the method disclosed above, the lens is processed, wiped, ultrasonically cleaned, and dried. Next, a hard coating is applied to both sides of the lens via dip coating. Specifically, the lens is immersed in a liquid solution of MP 7110 with a mass percentage of 22% at a temperature of 16° C. with a lifting speed of 2.5 mm/s. Once the hard coating is applied to the lens, the hard coating is dried by placing the lens in an approximately 65° C. environment for about 10 minutes. Subsequently, the lens is placed in a curing oven at about 115° C. for about 180 minutes so that the hard coating can solidify.

The performance test results of each of these four examples as compared to the functional criterion is provided in Table 1. Although the data in Table 1 represents the antibacterial lenses having the properties disclosed in the four examples above, these values are also representative of various other coated lenses that might be arranged or configured slightly differently than the noteworthy antibacterial lenses.

TABLE 1
Performance Test Results of Examples 1-4

| | | Example | Example | Example | Example |
|---|---|---|---|---|---|
| | Criterion | 1 | 2 | 3 | 4 |
| Contact Angle | ≥110° | 115° | 114° | 107° | 70° |
| Boil Adhesion | ≥95% | OK | OK | OK | OK |
| Drop Ball Test | Complies with FDA | OK | OK | OK | OK |
| E. coli ATCC 8739 Antimicrobial rate | Compliance with EN-166 | OK | OK | OK | OK |
| Staphylococcus aureus ATCC 6538P | ≥99% | 99.9% | 99.9% | NG | NG |
| Antibacterial rate | | | | | |
| Surface Hardness | ≥5H | 7H | 7H | 7H | 6H |
| 380-780 nm Transmittance Rate, % | ≥75% | 97.57% | 97.46% | 97.51% | 92.3% |

First, the performance test results emphasize that the antibacterial lenses produced in accordance with the methods disclosed herein can kill bacteria. Specifically, the antibacterial lenses can reduce or eliminate at least 95% of bacteria. Optionally, the antibacterial lenses eliminate at least 99% of bacteria or about 99.9% of bacteria.

In some embodiments, the antibacterial lenses are especially effective against Escherichia coli ATCC 8739. In other embodiments, the antibacterial lenses are designed to target Staphylococcus aureus ATCC 6538P. Optionally, the antibacterial lenses can have a coating that is designed to reduce or eliminate both Escherichia coli ATCC 8739 and Staphylococcus aureus ATCC 6538P. This is alluded to in Table 1, above, which includes data obtained in accordance with the ISO 22196:2011 measurement of antibacterial activity on plastic and other nonporous surfaces. This is described in greater detail with respect to FIG. 2.

FIG. 2 illustrates antimicrobial capabilities of the antibacterial lenses, according to some embodiments of the present disclosure. In particular, FIG. 2 illustrates how the antibacterial lenses respond to Escherichia coli ATCC 8739 and Staphylococcus aureus ATCC 6538P as compared to a plastic film without antimicrobial activity. The test was conducted pursuant to the ISO 22196:2011 measurement of antibacterial activity on plastic and other nonporous surfaces.

In FIG. 2, Uo refers to the average of the common logarithm of the number of viable bacteria (in cells/cm²) recovered from the untreated test specimens immediately after inoculation. Ut refers to the average of the common logarithm of the number of viable bacteria (in cells/cm²) recovered from the untreated test specimens after 24 hours. At refers to the average of the common logarithm of the number of viable bacteria (in cells/cm²) recovered from the treated test specimens after 24 hours. R refers to the value of antimicrobial activity and is calculated by subtracting At from Ut (i.e., R=Ut−At). Finally, the antibacterial activity rate, R %, is the percentage of bacteria that was eliminated by the antibacterial lenses. That is, R %=[(B−C)/B]×100, where B is the arithmetic average of the number of bacteria (in cells/cm²) obtained from the control samples after 24 hours of incubation and C is the arithmetic average of the number of bacteria (in cells/cm²) obtained from the antibacterial lens samples after 24 hours of incubation.

According to the tests conducted on the antibacterial lens and using the calculations described above, the antibacterial lenses can significantly reduce bacterial activity, such as to eliminate about 99.9% of Escherichia coli ATCC 8739 and about 99.9% of Staphylococcus aureus ATCC 6538P.

Turning again to Table 1, the performance test results also indicate that the antibacterial lenses maintain a high surface hardness. The antibacterial lenses have a surface hardness of about 5 H or more, about 6 H or more, or about 7 H or more. In some embodiments, the surface hardness is about 5H, about 6 H, about 7 H, about 8 H, or more.

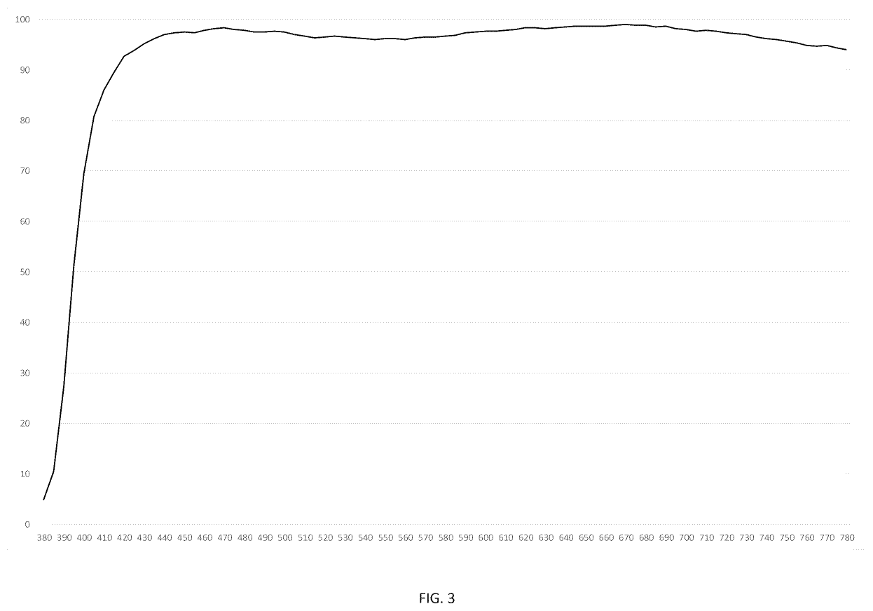

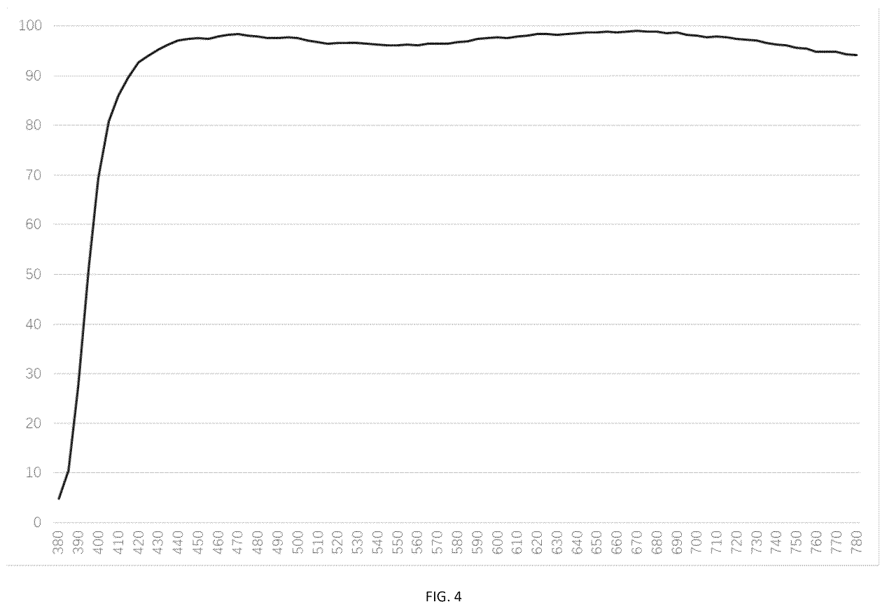

Referring now to Table 1 and FIGS. 3 and 4, the visible light spectrum can be transmitted through the antibacterial lenses, and FIGS. 3 and 4 illustrate the exceptional performance of the presently disclosed antibacterial lens, according to some embodiments. Although the values are representative of the antibacterial lenses having the properties disclosed above in the first and third examples, these values are also representative of various other coatings that might be arranged or configured slightly differently than the noteworthy antibacterial lenses.

FIG. 3 illustrates the spectrum of radiation that is transmitted by the first example of the antibacterial lens, according to some embodiments of the present disclosure. In particular, FIG. 3 illustrates the spectrum of visible light (that is, light with a wavelength between about 380 nm and about 780 nm) that is transmitted by the first example of the antibacterial lens, as described above. FIG. 3 illustrates that, in accordance with the data provided by Table 1, the first example of the antibacterial lens can transmit about 97.57% of visible light, which means that a wearer experiences high visibility, accurate color perception, and low glare when wearing the antibacterial lenses.

FIG. 4 illustrates the spectrum of radiation that is transmitted by the third example of the antibacterial lens, according to some embodiments of the present disclosure. FIG. 4 illustrates the spectrum of light with a wavelength between about 380 nm and 780 nm that is transmitted by the third example of the antibacterial lens, as described above. Consistent with the data provided in Table 1, the third example of the antibacterial lens transmits about 97.51% of visible light. Accordingly, like the first example, the third example of the antibacterial lens also provides the wearer with high visibility, accurate color perception, and low glare while also protecting the wearer from bacteria such as Escherichia coli ATCC 8739 and Staphylococcus aureus ATCC 6538P.

As shown by Table 1 and FIGS. 3 and 4, the antibacterial lenses described herein transmit significantly more visible light than conventional antibacterial lenses, which can only transmit about 75% of visible light.

### Illustration of Subject Technology as Clauses

Various examples of aspects of the disclosure are described as numbered clauses (1, 2, 3, etc.) for convenience. These are provided as examples, and do not limit the subject technology. Identifications of the figures and reference numbers are provided below merely as examples and for illustrative purposes, and the clauses are not limited by those identifications.
Clauses 1-3. In some embodiments (Clause 1), an antibacterial lens comprises: a lens comprising a first surface and a second surface opposite the first surface; a hard coating disposed on at least one of the first surface and the second surface; an antibacterial anti-reflection coating disposed on each hard coating, wherein the antibacterial anti-reflection coating is a layered structure comprising at least two of: a SiO2 layer having a thickness between about 2 nm and about 200 nm; a ZrO2 layer having a thickness between about 2 nm and about 140 nm; an ITO layer having a thickness between about 2 nm and about 15 nm; a ZnO layer having a thickness between about 2 nm and about 15 nm; and an Al2O3 layer having a thickness between about 2 nm and about 20 nm; and an antibacterial hydrophobic coating disposed on each antibacterial anti-reflection coating. In some embodiments (Clause 2), an antibacterial lens comprises: a double-sided lens; a hard coating disposed on at least one side of the double-sided lens; an antibacterial anti-reflection coating disposed on each hard coating and comprising a layered structure, wherein the layered structure comprises at least two of SiO2, ZrO2, ITO, ZnO, and Al2O3; and an antibacterial hydrophobic coating disposed on each anti-reflection coating. In some embodiments (Clause 3), an antibacterial coating for a lens comprises a layered structure having at least two of SiO2, ZrO2, ITO, ZnO, and Al2O3.
Clauses 4-8. In embodiments of any of the preceding Clauses, the lens comprises a resin lens (Clause 4). In embodiments of any of the preceding Clauses, the lens comprises a refraction index between about 1.34 and about 1.89 (Clause 5); in embodiments of any of the preceding Clauses, the lens comprises a refraction index between about 1.49 and about 1.74 (Clause 6); in embodiments of any of the preceding Clauses, the lens comprises a refraction index of about 1.56 (Clause 7); and in embodiments of any of the preceding Clauses, the lens comprises a refraction index of about 1.49 (Clause 8).
Clauses 9-17. In embodiments of any of the preceding Clauses, the hard coating is disposed on both the first surface and the second surface (Clause 9). In embodiments of any of the preceding Clauses, the hard coating comprises an organosilicon hard coating liquid (Clause 10); in embodiments of any of the preceding Clauses, the hard coating comprises a silicone (Clause 11); and in embodiments of any of the preceding Clauses, the hard coating comprises an abrasion resistant coating (Clause 12), wherein, in embodiments of Clause 12, the abrasion resistant coating comprises a mass percentage of about 22% (Clause 13). In embodiments of any of the preceding Clauses, the hard coating comprises a polysiloxane-based thermal cure coating with a 1.49 refraction index (Clause 14), wherein, in embodiments of Clause 14, the polysiloxane-based thermal cure coating comprises a mass percentage of about 22% (Clause 15). In embodiments of any of the preceding Clauses, the hard coating comprises a thickness between about 0.5 μm and 12 μm (Clause 16); and in embodiments of any of the preceding Clauses, the hard coating comprises a thickness between about 1 μm and 10 μm (Clause 17).
Clauses 18-22. In embodiments of any of the preceding Clauses, the layered structure comprises at least two of: a SiO2 layer having a thickness between about 5 nm and about 180 nm; a ZrO2 layer having a thickness between about 5 nm and about 120 nm; an ITO layer having a thickness between about 5 nm and about 10 nm; a ZnO layer having a thickness between about 5 nm and about 10 nm; and an Al2O3 layer having a thickness between about 5 nm and about 15 nm (Clause 18). In embodiments of any of the preceding Clauses, the layered structure comprises: a first SiO2 layer having a thickness between about 80 nm and about 180 nm; a first ZrO2 layer having a thickness between about 5 nm and about 60 nm; a second SiO2 layer having a thickness between about 5 nm and about 80 nm; a second ZrO2 layer having a thickness between about 20 nm and about 80 nm; a first ITO layer having a thickness between about 5 nm and about 10 nm; a first ZnO layer having a thickness between about 5 nm and about 10 nm; a first Al2O3 layer having a thickness between about 5 nm and about 15 nm; and a third SiO2 layer having a thickness between about 60 nm and about 150 nm (Clause 19). In embodiments of any of the preceding Clauses, the layered structure comprises: a first SiO2 layer having a thickness of about 129 nm; a first ZrO2 layer having a thickness of about 22 nm; a second SiO2 layer having a thickness of about 25 nm; a second ZrO2 layer having a thickness of about 40 nm; a first ITO layer having a thickness of about 5 nm; a first ZnO layer having a thickness of about 7 nm; a first Al2O3 layer having a thickness of about 8 nm; and a third SiO2 layer having a thickness of about 95 nm (Clause 20). In embodiments of any of the preceding Clauses, the layered structure comprises: a first SiO2 layer having a thickness of about 110 nm; a first ZrO2 layer having a thickness of about 45 nm; a second SiO2 layer having a thickness of about 55 nm; a second ZrO2 layer having a thickness of about 120 nm; a first ITO layer having a thickness of about 6 nm; a first ZnO layer having a thickness of about 7 nm; a first Al2O3 layer having a thickness of about 8 nm; and a third SiO2 layer having a thickness of about 90 nm (Clause 21). In embodiments of any of the preceding Clauses, the layered structure comprises: a first SiO2 layer having a thickness of about 85 nm; a first ZrO2 layer having a thickness of about 35 nm; a second SiO2 layer having a thickness of about 60 nm; a second ZrO2 layer having a thickness of about 100 nm; a first ITO layer having a thickness of about 6 nm; a first Al2O3 layer having a thickness of about 6 nm; and a third SiO2 layer having a thickness of about 85 nm (Clause 22).
Clauses 23-28. In embodiments of any of the preceding Clauses, the antibacterial hydrophobic coating comprises silver (Clause 23). In embodiments of any of the preceding Clauses, the antibacterial hydrophobic coating comprises a thickness between about 5 nm and about 110 nm (Clause 24); in embodiments of any of the preceding Clauses, a thickness between about 10 nm and about 100 nm (Clause 25); in embodiments of any of the preceding Clauses, a thickness of about 35 nm (Clause 26); in embodiments of any of the preceding Clauses, a thickness of about 30 nm (Clause 27); and in embodiments of any of the preceding Clauses, a thickness of about 20 nm (Clause 28).
Clauses 29-34. In embodiments of any of the preceding Clauses, the lens comprises a surface hardness of at least 6 H (Clause 29) and/or at least 7 H (Clause 30) and/or about 7 H (Clause 31). In embodiments of any of the preceding Clauses, the lens is configured to transmit at least 92% of light with a wavelength between about 380 nm and about 780 nm (Clause 32); in embodiments of any of the preceding Clauses, to transmit at least 97% of light with a wavelength between about 380 nm and about 780 nm (Clause 33); and in embodiments of any of the preceding Clauses, to transmit about 97% of light with a wavelength between about 380 nm and about 780 nm (Clause 34).
Clauses 35-46. In embodiments of any of the preceding Clauses, the antibacterial anti-reflection coating and the antibacterial hydrophobic coating are configured to reduce or eliminate bacteria on the lens (Clause 35); to reduce or eliminate at least 95% of bacteria on the lens (Clause 36); to reduce or eliminate at least 99% of bacteria on the lens (Clause 37); and/or to reduce or eliminate about 99.9% of bacteria on the lens (Clause 38). In embodiments of any of the preceding Clauses, the antibacterial anti-reflection coating and the antibacterial hydrophobic coating are configured to reduce or eliminate Escherichia coli ATCC 8739 on the lens (Clause 39); to reduce or eliminate at least 95% of Escherichia coli ATCC 8739 on the lens (Clause 40); to reduce or eliminate at least 99% of Escherichia coli ATCC 8739 on the lens (Clause 41); and/or to reduce or eliminate about 99.9% of Escherichia coli ATCC 8739 on the lens (Clause 42). In embodiments of any of the preceding Clauses, the antibacterial anti-reflection coating and the antibacterial hydrophobic coating are configured to reduce or eliminate Staphylococcus aureus ATCC 6538P on the lens (Clause 43); to reduce or eliminate at least 95% of Staphylococcus aureus ATCC 6538P on the lens (Clause 44); to reduce or eliminate at least 99% of Staphylococcus aureus ATCC 6538P on the lens (Clause 45); and/or to reduce or eliminate about 99.9% of Staphylococcus aureus ATCC 6538P on the lens (Clause 46).
Clauses 47-49. In some embodiments (Clause 47), a method for manufacturing an antibacterial lens comprises: providing a lens, the lens comprising a first surface and a second surface opposite the first surface; applying a hard coating to at least one of the first surface and the second surface; depositing an antibacterial anti-reflection coating on each hard coating, wherein the antibacterial anti-reflection coating is a layered structure comprising at least two of SiO2, ZrO2, ITO, ZnO, and Al2O3; and depositing an antibacterial hydrophobic coating on each antibacterial anti-reflection coating. In some embodiments (Clause 48), a method for manufacturing an antibacterial lens comprises: providing a lens comprising a first surface and a second surface opposite the first surface; cleaning the lens; applying a hard coating to at least one of the first surface and the second surface; placing the lens in a vacuum coating chamber; vacuum coating each hard coating with an antibacterial anti-reflection coating by bombarding each hard coating with Ar to activate each hard coating and depositing the antibacterial anti-reflection coating on each hard coating with an electron gun, wherein the antibacterial anti-reflection coating is a layered structure comprising at least two of SiO2, ZrO2, ITO, ZnO, and Al2O3; and thermal evaporating an antibacterial hydrophobic coating on each antibacterial anti-reflection coating. In some embodiments (Clause 49), a method for manufacturing an antibacterial lens comprises: providing a lens comprising a first surface and a second surface opposite the first surface; applying a hard coating to at least one of the first surface and the second surface; placing the lens in a vacuum coating chamber; vacuum coating each hard coating with an antibacterial anti-reflection coating by bombarding each hard coating with Ar to activate each hard coating and depositing the antibacterial anti-reflection coating on each hard coating with an electron gun, wherein the antibacterial anti-reflection coating is a layered structure comprising at least two of: a SiO2 layer having a thickness between about 2 nm and about 200 nm; a ZrO2 layer having a thickness between about 2 nm and about 140 nm; an ITO layer having a thickness between about 2 nm and about 15 nm; a ZnO layer having a thickness between about 2 nm and about 15 nm; and an Al2O3 layer having a thickness between about 2 nm and about 20 nm; and thermal evaporating an antibacterial hydrophobic coating on each antibacterial anti-reflection coating.
Clauses 50-55. In embodiments of any of Clauses 47 to 49, cleaning the lens comprises wiping the lens, exposing the lens to ultrasonic waves, and drying the lens (Clause 50). In embodiments of any of Clauses 47 to 50, the method further comprises, after providing the lens, processing the lens to have a correction value (Clause 51). In embodiments of any of Clauses 47 to 51, the method further comprises, after providing the lens, surface grinding the first surface and the second surface of the lens (Clause 52). In embodiments of any of Clauses 47 to 52, applying the hard coating comprises applying the hard coating to both the first surface and the second surface (Clause 53). In embodiments of any of Clauses 47 to 53, applying the hard coating comprises dip coating the lens (Clause 54); and in embodiments of any of Clauses 47 to 54, applying the hard coating comprises spin coating the lens (Clause 55).
Clauses 56-64. In embodiments of any of Clauses 47 to 55, applying the hard coating comprises immersing the lens in the hard coating at an immersion temperature between about 10° C. and 20° C. (Clause 56); and in embodiments of any of Clauses 47 to 56, immersing the lens at an immersion temperature of about 16° C. (Clause 57). In embodiments of any of Clauses 47 to 57, applying the hard coating comprises immersing the lens in the hard coating at a lifting speed between about 1 mm/s and about 3 mm/s (Clause 58); in embodiments of any of Clauses 47 to 58, at a lifting speed of about 2.5 mm/s (Clause 59); and in embodiments of any of Clauses 47 to 59, at a lifting speed of about 1.5 mm/s (Clause 60). In embodiments of any of Clauses 47 to 60, the method further comprises, after applying the hard coating, drying the hard coating on the lens at a temperature between about 60° C. and 70° C. for a time between about 5 minutes and 15 minutes (Clause 61); and in embodiments of any of Clauses 47 to 61, drying the hard coating at a temperature of about 65° C. for a time of about 10 minutes (Clause 62). In embodiments of any of Clauses 47 to 62, the method further comprises, after drying the hard coating on the lens, placing the lens in a curing oven at a temperature between about 110° C. and about 120° C. for a time between about 170 minutes and about 190 minutes (Clause 63); and in embodiments of any of Clauses 47 to 63, placing the lens in a curing oven at a temperature of about 115° C. for a time of about 180 minutes (Clause 64).
Clauses 65-87. In embodiments of any of Clauses 47 to 64, placing the lens in the vacuum coating chamber comprises placing the lens in the vacuum coating chamber having a temperature between about 30° C. and about 60° C. (Clause 65); in embodiments of any of Clauses 47 to 65, between about 35° C. and about 55° C. (Clause 66); and in embodiments of any of Clauses 47 to 66, about 40° C. (Clause 67). In embodiments of any of Clauses 47 to 67, placing the lens in the vacuum coating chamber comprises placing the lens in the vacuum coating chamber having a pressure between about 3.0×10-2 Pa and about 3.0×10-6 Pa (Clause 68); in embodiments of any of Clauses 47 to 68, between about 3.0×10-3 Pa and about 3.0×10-5 Pa (Clause 69); in embodiments of any of Clauses 47 to 69, about 3.0×10-3 Pa (Clause 70); and in embodiments of any of Clauses 47 to 70, about 1.0×10-3 Pa (Clause 71). In embodiments of any of Clauses 47 to 71, placing the lens in the vacuum coating chamber comprises placing the lens in the vacuum coating chamber having an anode voltage between about 80 V and about 130 V (Clause 72); in embodiments of any of Clauses 47 to 72, between about 90 V and about 120 V (Clause 73); in embodiments of any of Clauses 47 to 73, about 100 V (Clause 74); and in embodiments of any of Clauses 47 to 74, about 110 V (Clause 75). In embodiments of any of Clauses 47 to 75, placing the lens in the vacuum coating chamber comprises placing the lens in the vacuum coating chamber having an anode current between about 0.5 A and 3.5 A (Clause 76); in embodiments of any of Clauses 47 to 76, between about 1 A and 3 A (Clause 77); in embodiments of any of Clauses 47 to 77, about 3 A (Clause 78); and in embodiments of any of Clauses 47 to 78, about 1.5 A (Clause 79). In embodiments of any of Clauses 47 to 79, placing the lens in the vacuum coating chamber comprises placing the lens in the vacuum coating chamber having an O2 flow rate between about 0 sccm and about 40 sccm (Clause 80); in embodiments of any of Clauses 47 to 80, between about 0 sccm and about 35 sccm (Clause 81); in embodiments of any of Clauses 47 to 81, about 30 sccm (Clause 82); and in embodiments of any of Clauses 47 to 82, about 28 sccm (Clause 83). In embodiments of any of Clauses 47 to 83, placing the lens in the vacuum coating chamber comprises placing the lens in the vacuum coating chamber having an Ar flow rate between about 0 sccm and about 55 sccm (Clause 84); in embodiments of any of Clauses 47 to 84, between about 0 sccm and about 50 sccm (Clause 85); in embodiments of any of Clauses 47 to 85, about 40 sccm (Clause 86); and in embodiments of any of Clauses 47 to 86, about 36 sccm (Clause 87).
Clauses 88-107. In embodiments of any of Clauses 47 to 87, depositing SiO2 comprises depositing SiO2 at an evaporation rate between about 0.1 nm/s and about 3.5 nm/s (Clause 88); in embodiments of any of Clauses 47 to 88, between about 0.3 nm/s and about 3 nm/s (Clause 89); in embodiments of any of Clauses 47 to 89, about 2 nm/s (Clause 90); and in embodiments of any of Clauses 47 to 90, about 1.3 nm/s (Clause 91). In embodiments of any of Clauses 47 to 91, depositing ZrO2 comprises depositing ZrO2 at an evaporation rate between about 0.05 nm/s and about 2.5 nm/s (Clause 92); in embodiments of any of Clauses 47 to 92, between about 0.1 nm/s and about 2 nm/s (Clause 93); in embodiments of any of Clauses 47 to 93, about 0.8 nm/s (Clause 94); and in embodiments of any of Clauses 47 to 94, about 0.6 nm/s (Clause 95). In embodiments of any of Clauses 47 to 95, depositing ITO comprises depositing ITO at an evaporation rate between about 0.05 nm/s and about 0.25 nm/s (Clause 96); in embodiments of any of Clauses 47 to 96, between about 0.1 nm/s and about 0.2 nm/s (Clause 97); and in embodiments of any of Clauses 47 to 97, about 0.1 nm/s (Clause 98). In embodiments of any of Clauses 47 to 98, depositing ZnO comprises depositing ZnO at an evaporation rate between about 0.005 nm/s and about 0.25 nm/s (Clause 99); in embodiments of any of Clauses 47 to 99, between about 0.01 nm/s and about 0.2 nm/s (Clause 100); and in embodiments of any of Clauses 47 to 100, about 0.1 nm/s (Clause 101). In embodiments of any of Clauses 47 to 101, depositing Al2O3 comprises depositing Al2O3 at an evaporation rate between about 0.05 nm/s and about 0.35 nm/s (Clause 102); in embodiments of any of Clauses 47 to 102, between about 0.1 nm/s and about 0.3 nm/s (Clause 103); in embodiments of any of Clauses 47 to 103, about 0.3 nm/s (Clause 104); and in embodiments of any of Clauses 47 to 104, about 0.2 nm/s (Clause 105). In embodiments of any of Clauses 47 to 105, depositing the antibacterial anti-reflection coating on each hard coating with an electron gun comprises using an electron gun with a power between about 5% and 55% (Clause 106); and in embodiments of any of Clauses 47 to 106, using an electron gun with a power between about 10% and 50% (Clause 107).
Clauses 108-112. In embodiments of any of Clauses 47 to 107, thermal evaporating the antibacterial hydrophobic coating on each antibacterial anti-reflection coating comprises using resistive thermal radiation heating with a power between about 5% and 20% (Clause 108); and in embodiments of any of Clauses 47 to 108, using resistive thermal radiation heating with a power between about 10% and 15% (Clause 109). In embodiments of any of Clauses 47 to 109, thermal evaporating the antibacterial hydrophobic coating on each antibacterial anti-reflection coating comprises depositing the antibacterial hydrophobic coating at an evaporation rate between about 0.05 nm/s and about 0.3 mm/s (Clause 110); in embodiments of any of Clauses 47 to 110, depositing the antibacterial hydrophobic coating at an evaporation rate of about 0.2 nm/s (Clause 111); and in embodiments of any of Clauses 47 to 111, depositing the antibacterial hydrophobic coating at an evaporation rate of about 0.1 nm/s (Clause 112).

### Further Considerations

In some embodiments, any of the clauses herein may depend from any one of the independent clauses or any one of the dependent clauses. In one aspect, any of the clauses (e.g., dependent or independent clauses) may be combined with any other one or more clauses (e.g., dependent or independent clauses). In one aspect, a claim may include some or all of the words (e.g., steps, operations, means or components) recited in a clause, a sentence, a phrase or a paragraph. In one aspect, a claim may include some or all of the words recited in one or more clauses, sentences, phrases or paragraphs. In one aspect, some of the words in each of the clauses, sentences, phrases or paragraphs may be removed. In one aspect, additional words or elements may be added to a clause, a sentence, a phrase or a paragraph. In one aspect, the subject technology may be implemented without utilizing some of the components, elements, functions or operations described herein. In one aspect, the subject technology may be implemented utilizing additional components, elements, functions or operations.

The foregoing description is provided to enable a person skilled in the art to practice the various configurations described herein. While the subject technology has been particularly described with reference to the various figures and configurations, it should be understood that these are for illustration purposes only and should not be taken as limiting the scope of the subject technology.

There may be many other ways to implement the subject technology. Various functions and elements described herein may be partitioned differently from those shown without departing from the scope of the subject technology. Various modifications to these configurations will be readily apparent to those skilled in the art, and generic principles defined herein may be applied to other configurations. Thus, many changes and modifications may be made to the subject technology, by one having ordinary skill in the art, without departing from the scope of the subject technology.

It is understood that the specific order or hierarchy of steps in the processes disclosed is an illustration of exemplary approaches. Based upon design preferences, it is understood that the specific order or hierarchy of steps in the processes may be rearranged. Some of the steps may be performed simultaneously. The accompanying method claims present elements of the various steps in a sample order and are not meant to be limited to the specific order or hierarchy presented.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

Terms such as “top,” “bottom,” “front,” “rear” and the like as used in this disclosure should be understood as referring to an arbitrary frame of reference, rather than to the ordinary gravitational frame of reference. Thus, a top surface, a bottom surface, a front surface, and a rear surface may extend upwardly, downwardly, diagonally, or horizontally in a gravitational frame of reference.

Furthermore, to the extent that the term “include,” “have,” or the like is used in the description or the claims, such term is intended to be inclusive in a manner similar to the term “comprise” as “comprise” is interpreted when employed as a transitional word in a claim.

As used herein, the term “about” is relative to the actual value stated, as will be appreciated by those of skill in the art, and allows for approximations, inaccuracies and limits of measurement under the relevant circumstances. In one or more aspects, the terms “about,” “substantially,” and “approximately” may provide an industry-accepted tolerance for their corresponding terms and/or relativity between items, such as a tolerance of from less than one percent to 10 percent of the actual value stated, and other suitable tolerances.

As used herein, the term “comprising” indicates the presence of the specified integer(s), but allows for the possibility of other integers, unspecified. This term does not imply any particular proportion of the specified integers. Variations of the word “comprising,” such as “comprise” and “comprises,” have correspondingly similar meanings.

The word “exemplary” is used herein to mean “serving as an example, instance, or illustration.” Any embodiment described herein as “exemplary” is not necessarily to be construed as preferred or advantageous over other embodiments.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

Although the detailed description contains many specifics, these should not be construed as limiting the scope of the subject technology but merely as illustrating different examples and aspects of the subject technology. It should be appreciated that the scope of the subject technology includes other embodiments not discussed in detail above.

Various other modifications, changes and variations may be made in the arrangement, operation and details of the method and apparatus of the subject technology disclosed herein without departing from the scope of the present disclosure. In addition, it is not necessary for a device or method to address every problem that is solvable (or possess every advantage that is achievable) by different embodiments of the disclosure in order to be encompassed within the scope of the disclosure. The use herein of “can” and derivatives thereof shall be understood in the sense of “possibly” or “optionally” as opposed to an affirmative capability.

What is claimed is:

1. An antibacterial lens, comprising:
a lens substrate comprising a first surface and a second surface opposite the first surface;
a hard coating disposed on at least one of the first surface and the second surface;
an anti-reflection coating disposed on the hard coating, the anti-reflection coating comprising a layered structure including at least one SiO₂ layer and at least one ZrO₂ layer; and
a hydrophobic coating disposed on the anti-reflection coating.

2. The antibacterial lens of claim 1, wherein the hydrophobic coating comprising silver.

3. The antibacterial lens of claim 1, wherein the lens substrate has a refractive index between about 1.34 and about 1.89.

4. The antibacterial lens of claim 1, wherein the hard coating is disposed on both the first surface and the second surface, and wherein the anti-reflection coating and the hydrophobic coating are disposed on each hard coating.

5. The antibacterial lens of claim 1, wherein the hard coating comprises a polysiloxane-based thermal cure coating and has a thickness between about 0.5 μm and about 12 μm.

6. The antibacterial lens of claim 1, wherein the layered structure further comprises an ITO layer, a ZnO layer, and an Al₂O₃ layer.

7. The antibacterial lens of claim 6, wherein the ZnO layer is disposed between the ITO layer and the Al₂O₃ layer.

8. The antibacterial lens of claim 7, wherein the layered structure comprises, in order from the hard coating toward the hydrophobic coating: a first SiO₂ layer; a first ZrO₂ layer; a second SiO₂ layer; a second ZrO₂ layer; the ITO layer; the ZnO layer; the Al₂O₃ layer; and a third SiO₂ layer.

9. The antibacterial lens of claim 1, wherein (i) the hydrophobic coating has a thickness between about 5 nm and about 110 nm, and (ii) when tested in accordance with ISO 22196:2011, the lens reduces viable bacteria of Escherichia coli ATCC 8739 or Staphylococcus aureus ATCC 6538P by at least 95% after 24 hours.

10. An antibacterial anti-reflection coating for a lens, comprising a multilayer structure comprising:
at least one SiO₂ layer;
at least one ZrO₂ layer;
an ITO layer;
a ZnO layer; and
an Al₂O₃ layer,
wherein the ZnO layer is disposed between the ITO layer and the Al₂O₃ layer.

11. The antibacterial anti-reflection coating of claim 10, wherein the multilayer structure comprises, in order: a first SiO₂ layer; a first ZrO₂ layer; a second SiO₂ layer; a second ZrO₂ layer; the ITO layer; the ZnO layer; the Al₂O₃ layer; and a third SiO₂ layer.

12. The antibacterial anti-reflection coating of claim 11, wherein:
the first SiO₂ layer has a thickness between about 80 nm and about 180 nm;
the first ZrO₂ layer has a thickness between about 5 nm and about 60 nm;
the second SiO₂ layer has a thickness between about 5 nm and about 80 nm;
the second ZrO₂ layer has a thickness between about 20 nm and about 80 nm;
the ITO layer has a thickness between about 5 nm and about 10 nm;
the ZnO layer has a thickness between about 5 nm and about 10 nm;
the Al₂O₃ layer has a thickness between about 5 nm and about 15 nm; and
the third SiO₂ layer has a thickness between about 60 nm and about 150 nm.

13. The antibacterial anti-reflection coating of claim 11, wherein:
the first SiO₂ layer has a thickness of about 129 nm;
the first ZrO₂ layer has a thickness of about 22 nm;
the second SiO₂ layer has a thickness of about 25 nm;
the second ZrO₂ layer has a thickness of about 40 nm;
the ITO layer has a thickness of about 5 nm;
the ZnO layer has a thickness of about 7 nm;
the Al₂O₃ layer has a thickness of about 8 nm; and
the third SiO₂ layer has a thickness of about 95 nm.

14. A method of manufacturing an antibacterial lens, comprising:
providing a lens substrate comprising a first surface and a second surface opposite the first surface;
applying a hard coating to at least one of the first surface and the second surface;
placing the lens substrate in a vacuum coating chamber;
bombarding the hard coating with Ar to activate the hard coating;
depositing, with an electron gun, an anti-reflection coating on the hard coating, the anti-reflection coating comprising a multilayer structure including at least one SiO₂ layer, at least one ZrO₂ layer, an ITO layer, a ZnO layer, and an Al₂O₃ layer; and
thermally evaporating a hydrophobic coating comprising silver on the anti-reflection coating.

15. The method of claim 14, further comprising, prior to applying the hard coating, cleaning the lens substrate by wiping, exposing the lens substrate to ultrasonic waves, and drying the lens substrate.

16. The method of claim 14, further comprising, after providing the lens substrate, processing the lens substrate to have a correction value and surface grinding the first surface and the second surface.

17. The method of claim 14, wherein applying the hard coating comprises dip coating the lens substrate by immersing the lens substrate in the hard coating at an immersion temperature between about 10° C. and about 20° C. and lifting the lens substrate at a lifting speed between about 1 mm/s and about 3 mm/s.

18. The method of claim 14, further comprising:
after applying the hard coating, drying the hard coating at a temperature between about 60° C. and about 70° C. for a time between about 5 minutes and about 15 minutes; and
after drying, curing the hard coating at a temperature between about 110° C. and about 120° C. for a time between about 170 minutes and about 190 minutes.

19. The method of claim 14, wherein, during depositing the anti-reflection coating, the vacuum coating chamber has a temperature between about 30° C. and about 60° C. and a pressure between about 3.0×10⁻² Pa and about 3.0×10⁻⁶ Pa.

20. The method of claim 14, wherein depositing the anti-reflection coating comprises depositing:
SiO₂ at an evaporation rate between about 0.1 nm/s and about 3.5 nm/s;
ZrO₂ at an evaporation rate between about 0.05 nm/s and about 2.5 nm/s;
ITO at an evaporation rate between about 0.05 nm/s and about 0.25 nm/s;
ZnO at an evaporation rate between about 0.005 nm/s and about 0.25 nm/s; and
Al₂O₃ at an evaporation rate between about 0.05 nm/s and about 0.35 nm/s,
and wherein thermally evaporating the hydrophobic coating comprises depositing the hydrophobic coating at an evaporation rate between about 0.05 nm/s and about 0.3 nm/s.
